(19) United States
(12) Patent Application Publication
(10) Pub. No.: US 2026/0081607 A1
(43) Pub. Date: Mar. 19, 2026

(54) Variable Bypass Clock During Re-Lock Interval for Clock Control Circuitry

(71) Applicant: Apple Inc., Cupertino, CA (US)

(72) Inventors: Angel E. Socarras, Lake Mary, FL (US); Benoit M. Jubelin, Austin, TX (US); Vivek Oppula, Lakeway, TX (US)

(21) Appl. No.: 18/888,504

(22) Filed: Sep. 18, 2024

(51) Int. Cl. H03L 7/08

(52) U.S. Cl. CPC H03L 7/08

(57) ABSTRACT

Techniques are disclosed for managing clock signals during transitions between performance states (P-states) in processors. In some embodiments, an apparatus includes processor circuitry configured to operate based on an input clock signal at different input clock frequencies in different performance states. Phase-locked loop (PLL) circuitry provides the input clock signal at the different input clock frequencies. Bypass circuitry provides a bypass clock signal during different re-lock intervals in which the PLL circuitry adjusts the frequency of the input clock signal for a change from a first performance state to a second performance state. The bypass circuitry is configured to provide the bypass clock signal at a first frequency during a first re-lock interval and at a second, different frequency during a second re-lock interval. Dither circuitry may dither the bypass clock signal during the re-lock intervals, based on factors such as the origin and target performance states.

### BACKGROUND

### Technical Field

This disclosure relates generally to computer processors and more particularly to bypass clocks for managing clock signal transitions.

### Description of Related Art

Modern processors may dynamically adjust operating frequencies to balance performance and power consumption efficiently. For example, these adjustments may be managed through performance states (P-states) with different clock frequencies. Clock control circuitry such as phase-locked loops (PLLs) may be used to generate stable clock signals. The PLL may re-lock to a new frequency for a P-state transition and may not provide a stable clock signal during the re-lock interval. Therefore, control circuitry may provide a bypass clock signal during the re-lock period, typically at a lower frequency than the frequencies of the current and target P-states.

### BRIEF DESCRIPTION OF DRAWINGS

FIG. 1A is a diagram illustrating an overview of example graphics processing operations, according to some embodiments.

FIG. 1B is a block diagram illustrating an example graphics unit, according to some embodiments.

FIG. 2 is a block diagram illustrating an example system with an adjustable bypass clock, according to some embodiments.

FIG. 3 is a block diagram illustrating example dither circuitry for the bypass clock, according to some embodiments.

FIG. 4 is a block diagram illustrating example dither circuitry shared by the PLL output and bypass clock, according to some embodiments.

FIG. 5 is a block diagram illustrating an example of a PLL configured to generate the bypass clock, according to some embodiments.

FIG. 6 is an example diagram illustrating example bypass frequency selection during P-state transitions, according to some embodiments.

FIG. 7 is an example diagram illustrating example dithered bypass frequencies during P-state transitions, according to some embodiments.

FIG. 8 is a flow diagram illustrating an example method, according to some embodiments.

FIG. 9 is a block diagram illustrating an example computing device, according to some embodiments.

FIG. 10 is a diagram illustrating example applications of disclosed systems and devices, according to some embodiments.

FIG. 11 is a block diagram illustrating an example computer-readable medium that stores circuit design information, according to some embodiments.

### DETAILED DESCRIPTION

As discussed above, managing clock frequencies during transitions between P-states may be important for modern processors, e.g., System on Chip (SoC) components, graphics processors (GPUs), and general-purpose processors (CPUs). In some examples, during P-state changes, the PLL may re-lock to a new frequency (also referred to as a target frequency) and control circuitry may provide a bypass block signal to maintain continuous processor operation during the re-lock interval. As processors become more advanced, P-state transitions may become more frequent, e.g., to properly balance power and performance. Using a lower frequency bypass signal may substantially reduce performance during P-state transitions, however. This issue may be compounded in environments where power efficiency and performance are important, e.g., mobile and high-performance computing. For example, a traditional fixed bypass clock may be set to a frequency lower than both the original and target P-state frequencies, e.g., to prevent potential damage during peak current scenarios.

In disclosed embodiments, a bypass clock with a variable frequency may offer a solution to at least some of the issues. For example, the bypass clock frequency may be dynamically adjusted based on various factors including, but not limited to, the current P-state, the target P-state, the difference between them, other operating parameters, or some combination thereof. In some aspects, this flexibility may allow the system to use a higher-frequency bypass clock that traditional techniques for certain transitions, thereby reducing the performance impact during PLL re-lock intervals. For example, the bypass clock frequency may be selected near the target P-state frequency, which may reduce the disparity between the operating frequencies during transitions. By providing a bypass clock frequency that is closer to the desired operating frequency, the disclosed embodiments may improve processor performance during state transitions and facilitate a smoother and more efficient operation.

In some embodiments, dither circuitry may smooth the transition from the source P-state frequency to the bypass frequency. Dither circuitry may be positioned in various locations, e.g., at a bypass clock output or shared by both bypass and PLL outputs. Control circuitry may determine whether to apply dithering, adjust the amount of dithering, or both based on various operating information (e.g., whether there is an increase or decrease in P-state, difference between P-states, etc.). In some embodiments, a dedicated PLL circuit is configured to provide the adjustable bypass clock.

### Graphics Processing Overview

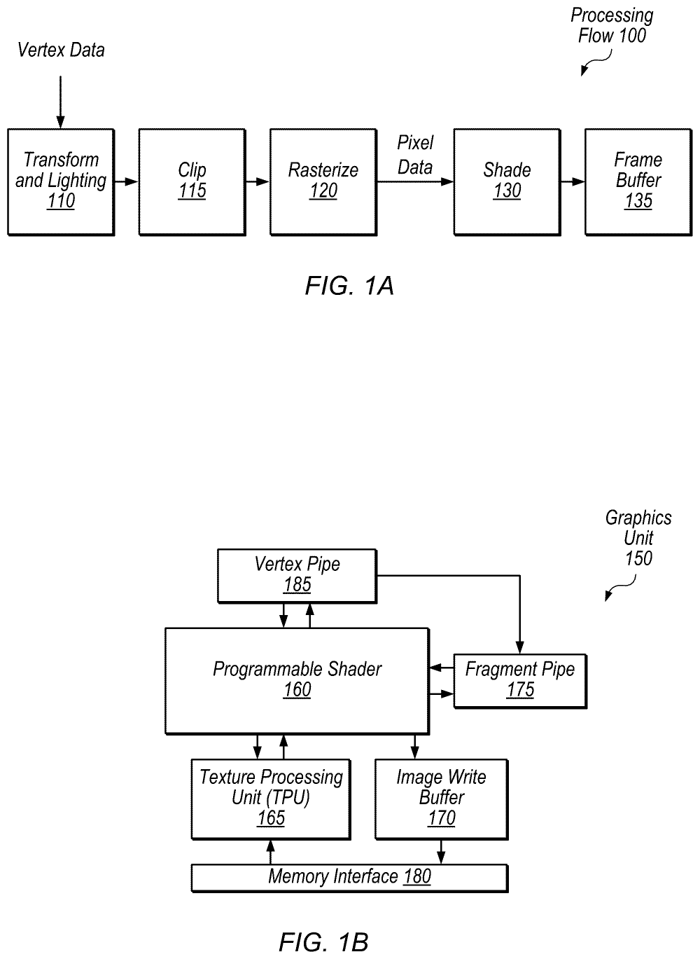

Referring to FIG. 1A, a flow diagram illustrating an example processing flow 100 for processing graphics data is shown. In some embodiments, transform and lighting procedure 110 may involve processing lighting information for vertices received from an application based on defined light source locations, reflectance, etc., assembling the vertices into polygons (e.g., triangles), and transforming the polygons to the correct size and orientation based on position in a three-dimensional space. Clip procedure 115 may involve discarding polygons or vertices that fall outside of a viewable area. In some embodiments, geometry processing may utilize object shaders and mesh shaders for flexibility and efficient processing prior to rasterization. Rasterize procedure 120 may involve defining fragments within each polygon and assigning initial color values for each fragment, e.g., based on texture coordinates of the vertices of the polygon. Fragments may specify attributes for pixels which they overlap, but the actual pixel attributes may be determined based on combining multiple fragments (e.g., in a frame buffer), ignoring one or more fragments (e.g., if they are covered by other objects), or both. Shade procedure 130 may involve altering pixel components based on lighting, shadows, bump mapping, translucency, etc. Shaded pixels may be assembled in a frame buffer 135. Modern GPUs typically include programmable shaders that allow customization of shading and other processing procedures by application developers. Thus, in various embodiments, the example elements of FIG. 1A may be performed in various orders, performed in parallel, or omitted. Additional processing procedures may also be implemented.

Referring now to FIG. 1B, a simplified block diagram illustrating a graphics unit 150 is shown, according to some embodiments. In the illustrated embodiment, graphics unit 150 includes programmable shader 160, vertex pipe 185, fragment pipe 175, texture processing unit (TPU) 165, image write buffer 170, and memory interface 180. In some embodiments, graphics unit 150 is configured to process both vertex and fragment data using programmable shader 160, which may be configured to process graphics data in parallel using multiple execution pipelines or instances.

Vertex pipe 185, in the illustrated embodiment, may include various fixed-function hardware configured to process vertex data. Vertex pipe 185 may be configured to communicate with programmable shader 160 in order to coordinate vertex processing. In the illustrated embodiment, vertex pipe 185 is configured to send processed data to fragment pipe 175 or programmable shader 160 for further processing.

Fragment pipe 175, in the illustrated embodiment, may include various fixed-function hardware configured to process pixel data. Fragment pipe 175 may be configured to communicate with programmable shader 160 in order to coordinate fragment processing. Fragment pipe 175 may be configured to perform rasterization on polygons from vertex pipe 185 or programmable shader 160 to generate fragment data. Vertex pipe 185 and fragment pipe 175 may be coupled to memory interface 180 (coupling not shown) in order to access graphics data.

Programmable shader 160, in the illustrated embodiment, is configured to receive vertex data from vertex pipe 185 and fragment data from fragment pipe 175 and TPU 165. Programmable shader 160 may be configured to perform vertex processing tasks on vertex data which may include various transformations and adjustments of vertex data. Programmable shader 160, in the illustrated embodiment, is also configured to perform fragment processing tasks on pixel data such as texturing and shading, for example. Programmable shader 160 may include multiple sets of multiple execution pipelines for processing data in parallel.

In some embodiments, programmable shader includes pipelines configured to execute one or more different SIMD groups in parallel. Each pipeline may include various stages configured to perform operations in a given clock cycle, such as fetch, decode, issue, execute, etc. The concept of a processor “pipeline” is well understood, and refers to the concept of splitting the “work” a processor performs on instructions into multiple stages. In some embodiments, instruction decode, dispatch, execution (i.e., performance), and retirement may be examples of different pipeline stages. Many different pipeline architectures are possible with varying orderings of elements/portions. Various pipeline stages perform such steps on an instruction during one or more processor clock cycles, then pass the instruction or operations associated with the instruction on to other stages for further processing.

The term “SIMD group” is intended to be interpreted according to its well-understood meaning, which includes a set of threads for which processing hardware processes the same instruction in parallel using different input data for the different threads. SIMD groups may also be referred to as SIMT (single-instruction, multiple-thread) groups, single instruction parallel thread (SIPT), or lane-stacked threads. Various types of computer processors may include sets of pipelines configured to execute SIMD instructions. For example, graphics processors often include programmable shader cores that are configured to execute instructions for a set of related threads in a SIMD fashion. Other examples of names that may be used for a SIMD group include: a wavefront, a clique, or a warp. A SIMD group may be a part of a larger thread group of threads that execute the same program, which may be broken up into a number of SIMD groups (within which threads may execute in lockstep) based on the parallel processing capabilities of a computer. In some embodiments, each thread is assigned to a hardware pipeline (which may be referred to as a “lane”) that fetches operands for that thread and performs the specified operations in parallel with other pipelines for the set of threads. Note that processors may have a large number of pipelines such that multiple separate SIMD groups may also execute in parallel. In some embodiments, each thread has private operand storage, e.g., in a register file. Thus, a read of a particular register from the register file may provide the version of the register for each thread in a SIMD group.

As used herein, the term “thread” includes its well-understood meaning in the art and refers to sequence of program instructions that can be scheduled for execution independently of other threads. Multiple threads may be included in a SIMD group to execute in lock-step. Multiple threads may be included in a task or process (which may correspond to a computer program). Threads of a given task may or may not share resources such as registers and memory. Thus, context switches may or may not be performed when switching between threads of the same task.

In some embodiments, multiple programmable shader units 160 are included in a GPU. In these embodiments, global control circuitry may assign work to the different sub-portions of the GPU which may in turn assign work to shader cores to be processed by shader pipelines.

TPU 165, in the illustrated embodiment, is configured to schedule fragment processing tasks from programmable shader 160. In some embodiments, TPU 165 is configured to pre-fetch texture data and assign initial colors to fragments for further processing by programmable shader 160 (e.g., via memory interface 180). TPU 165 may be configured to provide fragment components in normalized integer formats or floating-point formats, for example. In some embodiments, TPU 165 is configured to provide fragments in groups of four (a “fragment quad”) in a 2×2 format to be processed by a group of four execution pipelines in programmable shader 160.

Image write buffer 170, in some embodiments, is configured to store processed tiles of an image and may perform operations to a rendered image before it is transferred for display or to memory for storage. In some embodiments, graphics unit 150 is configured to perform tile-based deferred rendering (TBDR). In tile-based rendering, different portions of the screen space (e.g., squares or rectangles of pixels) may be processed separately. Memory interface 180 may facilitate communications with one or more of various memory hierarchies in various embodiments.

As discussed above, graphics processors typically include specialized circuitry configured to perform certain graphics processing operations requested by a computing system. This may include fixed-function vertex processing circuitry, pixel processing circuitry, or texture sampling circuitry, for example. Graphics processors may also execute non-graphics compute tasks that may use GPU shader cores but may not use fixed-function graphics hardware. As one example, machine learning workloads (which may include inference, training, or both) are often assigned to GPUs because of their parallel processing capabilities. Thus, compute kernels executed by the GPU may include program instructions that specify machine learning tasks such as implementing neural network layers or other aspects of machine learning models to be executed by GPU shaders. In some scenarios, non-graphics workloads may also utilize specialized graphics circuitry, e.g., for a different purpose than originally intended.

Further, various circuitry and techniques discussed herein with reference to graphics processors may be implemented in other types of processors in other embodiments. Other types of processors may include general-purpose processors such as CPUs or machine learning or artificial intelligence accelerators with specialized parallel processing capabilities. These other types of processors may not be configured to execute graphics instructions or perform graphics operations. For example, other types of processors may not include fixed-function hardware that is included in typical GPUs. Machine learning accelerators may include specialized hardware for certain operations such as implementing neural network layers or other aspects of machine learning models. Speaking generally, there may be design tradeoffs between the memory requirements, computation capabilities, power consumption, and programmability of machine learning accelerators. Therefore, different implementations may focus on different performance goals. Developers may select from among multiple potential hardware targets for a given machine learning application, e.g., from among generic processors, GPUs, and different specialized machine learning accelerators.

### Overview of Selectable Phase-Locked Loop and Bypass Clock

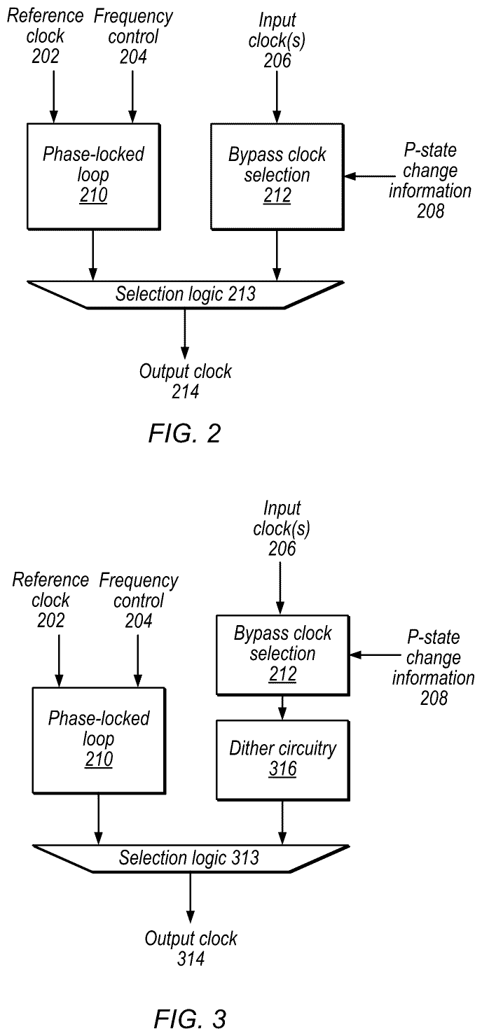

FIG. 2 is a block diagram illustrating an example system with an adjustable bypass clock, according to some embodiments. In the illustrated embodiment, selection circuitry 213 is configured to select between the output of PLL 210 and the output of bypass clock selection circuitry 212. For example, selection logic 213 may select the PLL 210 output when operating in a given P-state and select the output of circuitry 212 during a PLL re-lock interval. The output clock may be used as an input clock signal by processor circuitry (not shown). Note that the example circuitry of FIGS. 2-5 is included for purposes of illustration but is not intended to limit the scope of the present disclosure. Various disclosed circuitry may be implemented using other topologies, connectivity, etc.

In some embodiments, selection logic 213 is multiplexer (MUX) or any other circuity or logic component capable of selecting between multiple input signals (e.g., output of PLL 210, output of bypass clock selection 212) to produce a desired output signal (e.g., output clock 214).

In some embodiments, PLL 210 is configured to continuously adjust its output signal to match a frequency indicated by frequency control 204. PLL 210 may include a phase detector, a low-pass filter (also loop filter), and a voltage controlled oscillator (VCO). In some aspects, the VCO may generate an output signal of a frequency proportional to its input voltage. In some examples, the phase detector may compare reference clock 202 with the output of the VCO and output a voltage proportional to the phase difference between them. In some cases, the phase difference (e.g., an error signal) between reference clock 202 and the output of the VCO may be input to the low-pass filter. In some embodiments, the low-pass filter may then generate an error voltage based on the error signal, which may be input to the VCO. The VCO may subsequently increase or decrease its oscillator frequency such that the output of the VCO (e.g., the output of PLL 210) is locked in phase with reference clock 202. The PLL may implement frequency divider circuitry controlled by frequency control signal 204 to generate a stable frequency that is a multiple of the reference clock 202 frequency. Therefore PLL 210 may be configured to generate multiple different output clock frequencies although it may not provide a stable clock output when transitioning from one frequency to another (referred to as the re-lock interval).

In some embodiments, other types of circuits (e.g., instead of PLL 210) such as a digital frequency synthesizer (DFS) or direct digital synthesis (DDS) circuits may be used to generate stable frequency signals. Those skilled in the art will appreciate additional examples of methods to generate stable frequency signals and disclosed adjustable bypass clock techniques may be used with various appropriate clock generator circuits.

In some aspects, the output (e.g., stable clock signal) of PLL 210 may be used by a processor (e.g., selected via selection logic 213 as output clock 214) as its operating frequency. By way of example, processors may operate in different performance states, or P-states, to balance power consumption and performance requirements. In some embodiments, each P-state may have a corresponding frequency and source voltage. In some examples, a lower P-state may operate at a lower frequency and voltage compared to a higher P-state (e.g., P1 may refer to a lower frequency state than P3) which may conserve power and generate less heat.

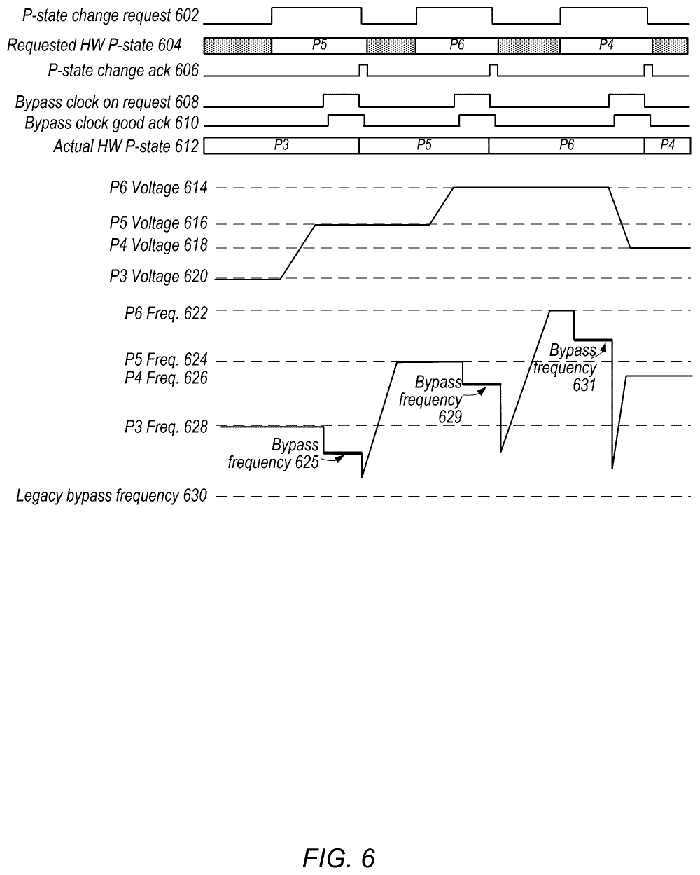

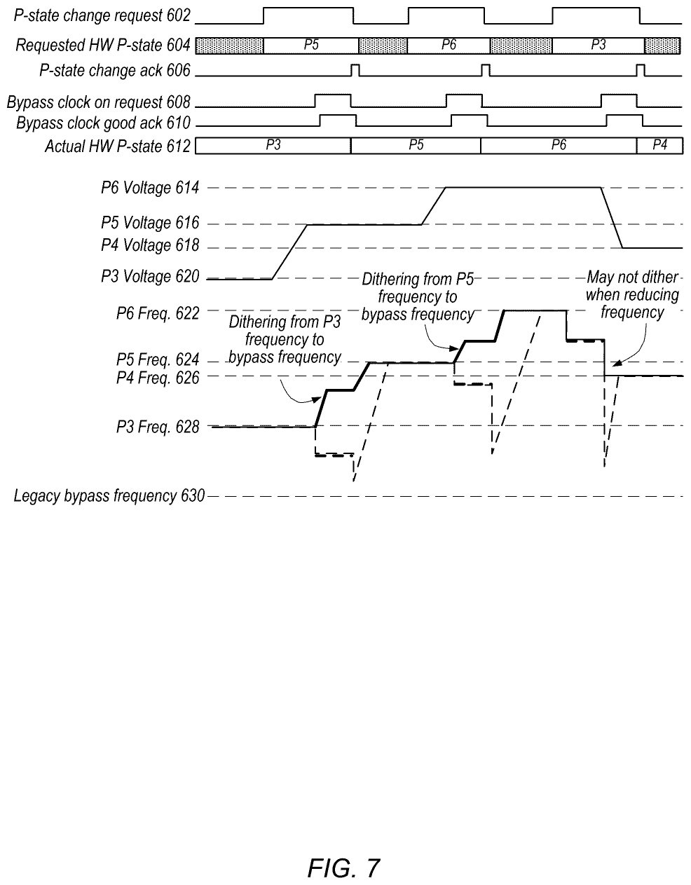

In some examples, when a processor transitions from an origin P-state to a target P-state (e.g., from P3 to P5 as illustrated in FIG. 6 and FIG. 7), PLL 210 may need to adjust its output frequency to match the new target frequency of the target P-state. In some aspects, during this transition, PLL 210 may re-lock to the frequency of the target P-state to allow for stable and continuous operation of the processor. In some embodiments, during the re-lock period, PLL 210 may temporarily be unable to provide a stable clock signal as it adjusts to the new target P-state frequency. To maintain continuous operation of the processor during the re-lock period, a bypass clock signal from circuitry 212 may be used.

Bypass clock selection 212, in some embodiments, receives one or more input clock(s) 206 and P-state change information 208 as input signals and output a bypass clock signal. By way of example, input clock(s) 206 may be implemented using System on Chip (SoC) clock mesh methodology. The input clock(s) 206 may provide reliable clock signals for the processor's operation (e.g., during PLL 210 re-lock intervals). In some aspects, P-state change information 208 may provide data about the current or origin P-state and the new or target P-state to bypass clock selection 212. In some instances, bypass clock selection 212 may use P-state change information 208 to select an input clock 206 (e.g., from one or more input clock(s) 206) to be used as an output signal (e.g., a bypass clock signal).

In some embodiments, bypass clock selection 212 is configured to select an input clock 206 as a bypass clock signal based on the current or origin P-state. For example, if the processor is transitioning from P3 to P5 as illustrated in FIG. 6 and FIG. 7, bypass clock selection 212 may select input clock 206 based on the frequency of P3. In some embodiments, bypass clock selection 212 may select an input clock 206 as a bypass clock signal based on the target P-state. For example, if the processor is transitioning from P3 to P5 as illustrated in FIG. 6 and FIG. 7, bypass clock selection 212 may select input clock 206 as a bypass clock signal based on the frequency of target P-state, P5. In some embodiments, bypass clock selection 212 may select an input clock 206 as a bypass clock signal based on the difference between the target P-state and origin P-state. For example, if the processor is transitioning from P3 to P5 as illustrated in FIG. 6 and FIG. 7, bypass clock selection 212 may select input clock 206 as a bypass clock signal based on the difference in frequency of target P-state, P5 and origin P-state, P3 (e.g., P5-P3).

In some embodiments, bypass clock selection circuitry 212 is configured to access a lookup table based P-state change information 208 to determine which clock input to select, e.g., the lookup table may be indexed by target P-state, difference between P-states, etc. and a given entry may indicate MUX control signals to select the corresponding appropriate bypass clock.

Note that while bypass clock select circuitry 212 may select from among multiple input clocks in some embodiments (e.g., using a MUX), in other embodiments it may receive a single input clock at a fixed frequency and may include divider circuitry configured to generate different output frequencies from the input clock, based on control information 208.

Various disclosed techniques may improve performance by maintaining the output clock 214 at a higher frequency for certain P-state transitions, relative to traditional techniques with fixed bypass clock frequencies.

### Overview of Selectable Phase-Locked Loop and Bypass Clock and Dither Circuitry

FIG. 3 is a block diagram illustrating example dither circuitry for the bypass clock, according to some embodiments. Note that various elements of FIG. 3 may be configured as discussed above with reference to FIG. 2. In the illustrated example, the system also includes dither circuitry 316. In the illustrated embodiment of FIG. 3, the output of bypass clock selection 212 is input to dither circuitry 316 which provides a dithered clock to selection logic 313.

In some embodiments, dither circuitry 316 may be used to smooth the transition from the source P-state frequency provided by PLL 210 to the selected bypass clock frequency, from the selected bypass clock frequency to the target P-state frequency, or both. In some cases, dither circuitry 316 is configured to apply dithering only when the target P-state is greater than the origin P-state. This may advantageously reduce or avoid situations where the bypass clock provides a frequency increase before the supply voltage has increased for the target P-state.

In some embodiments, dither circuitry 316 is configured to dither the bypass clock signal (e.g., output of bypass clock selection 212) by swallowing clock cycles (e.g., maintaining its output at its current level instead of changing it in response to one or more input clock edges). In some aspects, swallowing clock cycles may reduce the overall frequency of the bypass clock signal over a time interval which may reduce the speed of the transition to the higher frequency of the target P-state. Those skilled in the art will appreciate that alternative or additional methods for dithering that may be applied by dither circuitry 316.

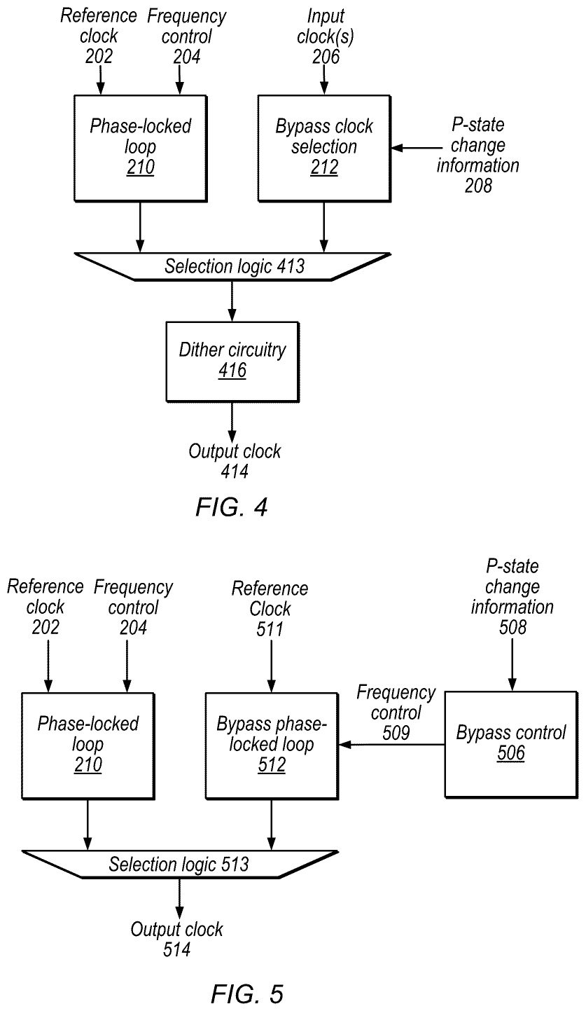

FIG. 4 is a block diagram illustrating example dither circuitry shared by the PLL output and bypass clock, according to some embodiments. Note that various elements of FIG. 4 may be configured as discussed above with reference to FIG. 2.

In the illustrated embodiment, dither circuitry 416 is shared for both the PLL output and the bypass clock (e.g., as selected via selection logic 413). In these embodiments, dither circuitry 416 may be used to dither the PLL output in various scenarios, without requiring separate dither circuitry from the dither circuitry for the bypass clock.

FIG. 5 is a block diagram illustrating an example of a PLL configured to generate the bypass clock, according to some embodiments. Note that various elements of FIG. 5 may be configured as discussed above with reference to FIG. 2.

In the illustrated embodiment of FIG. 5, a bypass phase-locked loop (PLL) 512 is configured to provide the bypass clock signal to the processor (e.g., during a re-lock interval). PLL 512 may be implemented using various PLL circuitry, e.g., similarly to PLL 210 discussed above with respect to FIG. 2. For example, bypass PLL 512 may continuously adjust its output signal based on reference clock 511. In some examples, bypass PLL 512 may include a phase detector, a low-pass filter (also loop filter), and a voltage controlled oscillator (VCO). In some embodiments, frequency control 509 is controlled by bypass control 506 which may receive P-state change information 508, such that the output of bypass PLL 512 may change or adjust based on the origin P-state and/or target P-state (e.g., and the difference between the target P-state and origin P-state).

In some embodiments, bypass control circuitry 506 may adjust the frequency control signal 509 in advance of a P-state change, e.g., so that the PLL 512 can re-lock to the selected bypass frequency prior to the re-lock interval for PLL 510 begins.

Using a PLL to generate the bypass clock may increase circuit area relative to the embodiments of FIGS. 2-4, for example, but may provide additional flexibility in selecting bypass clock frequencies and may also improve the stability of the bypass clock.

### Example Diagrams for P-state Transitions and Bypass Frequencies

FIG. 6 is an example diagram illustrating example bypass frequency selection during P-state transitions, according to some embodiments. In the illustrated example of FIG. 6, a processor is shown transitioning through various P-state frequencies starting with P3 frequency 628 to P5 frequency 624, then to P6 frequency 622, and then down to P4 frequency 626. The illustrated example of FIG. 6 also shows corresponding P-state voltages of P3 voltage 620 to P5 voltage 616, then to P6 voltage 614, and then down to P4 voltage 618.

In some aspects, actual HW P-state 612 illustrates the current P-state of the processor. The requested HW P-state 604 may illustrate a request to change the P-state of the processor which is also signaled by signal P-state change request 602. In some embodiments, when a request is made to change to a higher P-state (e.g., from P3 to P5) as shown by P-state change request 602 (e.g., transitioning from a low or inactive state to a high or active state), the voltage may begin to increase from the current P-state to the higher target P-state (e.g., P3 voltage 620 may increase to P5 voltage 616 when P-state change request 602 is in the high or active state).

In some embodiments, as discussed above, when a processor is transitioning to a new or target P-state and the PLL is re-locking to the target P-state frequency, a bypass clock signal may be used during the re-locking period. The bypass clock on request 608 signal may transition to a high state (which may also be referred to as an active state) to indicate a request for a bypass clock signal during a re-locking period of the PLL. In some examples, at some interval of time later, the bypass clock request may be acknowledged as illustrated by signal bypass clock good acknowledge 610 which may also transition to a high state.

In some examples, when the bypass clock is acknowledged (e.g., as illustrated by signal 610), the processor may transition to the frequency of the bypass clock signal (e.g., the MUX 213 as illustrated in FIG. 2 may select the output of bypass clock selection 212) as shown by bypass frequency 625 during the transition from P3 to P5 (e.g., a first re-lock interval), bypass frequency 629 during the transition from P5 to P6 (e.g., a second re-lock interval), and bypass frequency 631 during the transition from P6 to P4. As illustrated in FIG. 6, bypass frequencies 625, 629 and 631 are shown as a higher frequency compared to the legacy bypass frequency 630 (which represents a fixed bypass frequency that might be used in traditional implementations). In some embodiments, when the processor is transitioned to the new or target P-state (e.g., as illustrated by P-state change acknowledgement signal 606), the processor may resume utilizing the output of the PLL as an input clock signal (e.g., the MUX 213 as illustrated in FIG. 2 may select the output of PLL 210).

As shown, disclosed techniques may advantageously provide higher frequencies during bypass intervals, which may improve processor performance.

FIG. 7 is an example diagram illustrating example dithered bypass frequencies during P-state transitions, according to some embodiments. The illustrated example of FIG. 7 is shown depicting similar signals and P-state transitions as illustrated above with respect to FIG. 6 with the addition of dithering applied to the bypass frequencies (e.g., bypass frequencies 625, 629, 631). For example, dithering may be applied (e.g., via dither circuitry 316) to the bypass frequencies by swallowing clock cycles as discussed above with respect to FIG. 3. In some embodiments, during a transition from to a lower target P-state (e.g., from P6 to P4), dithering may not be applied. As discussed above, dithering during an increase to a bypass frequency may advantageously reduce or avoid situations where the supply voltage has not finished increasing to fully support the frequency change.

### Example Method

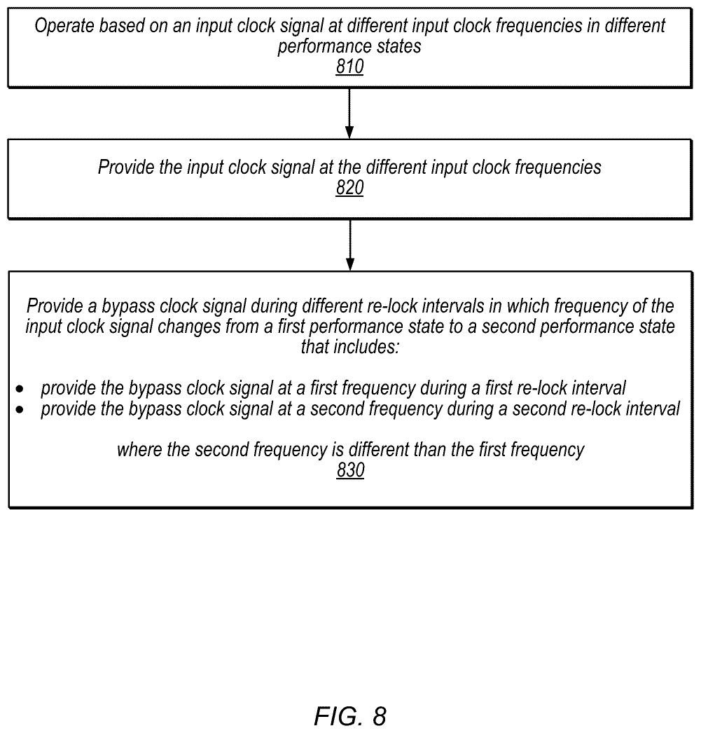

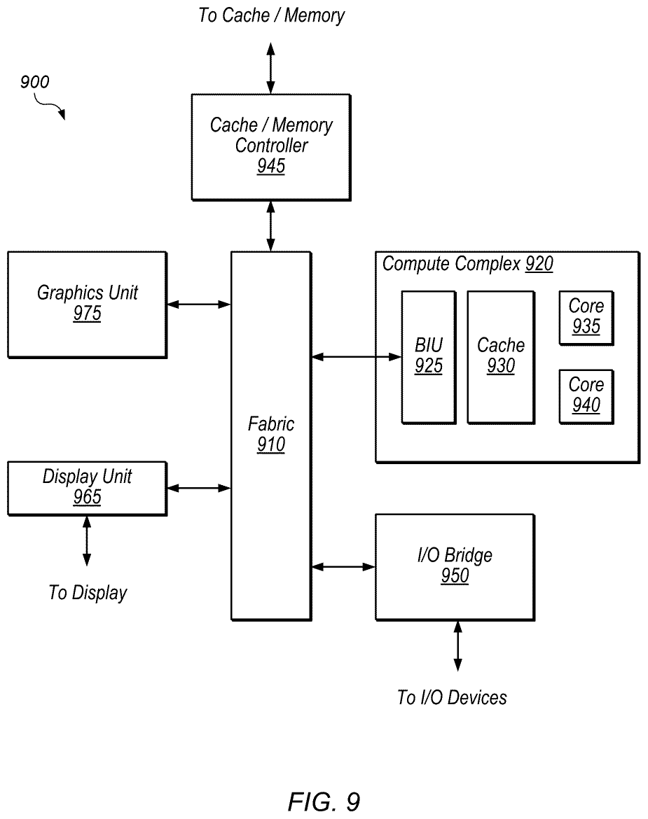

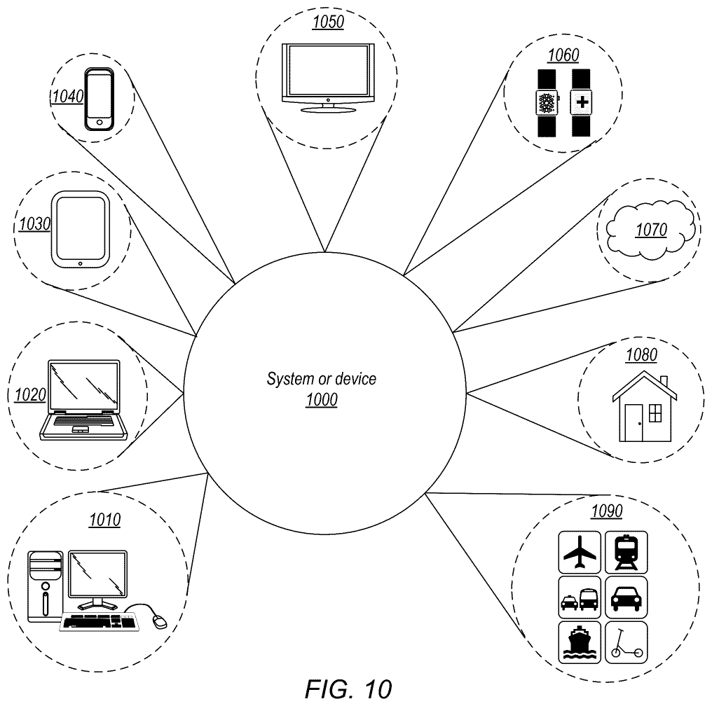

FIG. 8 is a flow diagram illustrating an example method for providing a bypass clock signal during re-lock intervals in which a PLL circuit adjusts frequency of the input clock signal, according to some embodiments. The method shown in FIG. 9 may be used in conjunction with any of the computer circuitry, systems, devices, elements, or components disclosed herein, among others. In various embodiments, some of the method elements shown may be performed concurrently, in a different order than shown, or may be omitted. Additional method elements may also be performed as desired.

At 810, in the illustrated embodiment, a computing system (e.g., a processor, SOC, or device) operates based on an input clock signal at different input clock frequencies in different performance states. For example, a processor may adjust its operating speed by changing the frequency of its input clock signal (e.g., output clock 214), depending on the current performance state (P-state).

At 820, in the illustrated embodiment, a PLL provides the input clock signal at different input clock frequencies. For example, a PLL (e.g., PLL 210) may provide an input clock signal to the processor via selection logic 213 at different input clock frequencies.

At 830, in the illustrated embodiment, the computing system (e.g., bypass clock selection 212) provides a bypass clock signal during different re-lock intervals in which frequency of the input clock signal changes from a first performance state (e.g., a given origin performance state such as a starting P-state as illustrated in the transitions shown in FIG. 6 and FIG. 7) to a second performance state (e.g., a given target performance state such as a target P-state as illustrated in the transitions shown in FIG. 6 and FIG. 7) that includes providing the bypass clock signal at a first frequency during a first re-lock interval and providing the bypass clock signal at a second frequency during a second re-lock interval, wherein the second frequency is different than the first frequency. For example, when PLL 210 adjusts its frequency during a re-lock interval (e.g., from a current or given origin P-state to a new or given target P-state), bypass clock selection 212 may provide a selectable bypass clock signal that may be used (e.g., as the input clock signal) by the processor.

In some embodiments, the computing system (e.g., bypass clock selection 212) is configured to determine the first frequency of the first re-lock interval based on a first origin performance state corresponding to the first re-lock interval. For example, bypass clock selection 212 may determine the first frequency (e.g., bypass frequency 625) based on a first origin performance state (e.g., P3) corresponding to the first re-lock interval (e.g., during the re-lock interval for the transition from P3 to P5).

In some embodiments, the computing system (e.g., bypass clock selection 212) is configured to determine the first frequency of the first re-lock interval based on a first target performance state corresponding to the first re-lock interval. For example, bypass clock selection 212 may determine the first frequency (e.g., bypass frequency 625) based on a first target performance state (e.g., P5) corresponding to the first re-lock interval (e.g., during the re-lock interval for the transition from P3 to P5).

In some embodiments, the computing system (e.g., bypass clock selection 212) is configured to determine the first frequency of the first re-lock interval based on a difference between a first target performance state and a first origin performance state corresponding to the first re-lock interval. For example, bypass clock selection 212 may determine the first frequency (e.g., bypass frequency 625) based on a difference (e.g., P5-P3) between a first target performance state (e.g., P5) and a first origin performance state (e.g., P3) corresponding to the first re-lock interval (e.g., during the re-lock interval for the transition from P3 frequency 628 to P5 frequency 624).

In some embodiments, the computing system is further configured to select between the input clock signal generated by the PLL clock generator and a second input signal associated with the bypass clock signal and dither the bypass clock signal during a given re-lock interval. For example, the computing system (e.g., selection logic 313) may select between the output of PLL 310 and bypass clock selection 312 and dither (e.g., via dither circuitry 316) the bypass clock signal (e.g., generated by bypass clock selection 312).

In some embodiments, the computing system is further configured to dither the bypass clock signal when the second performance state is greater than the first performance state, but not when the second performance state is lower than the first performance state. For example, for a given origin performance state (e.g., first performance state) transitioning to a given target performance state (e.g., second performance state), dithering may only be applied when the given target performance state is greater than the given origin performance state (e.g., such as a the transitions between P3 frequency 628 to P5 frequency 624 and P5 frequency 624 to P6 frequency 622, but not during the transition between P6 frequency 622 to P4 frequency 626).

### Example Device

Referring now to FIG. 9, a block diagram illustrating an example embodiment of a device 900 is shown. In some embodiments, elements of device 900 may be included within a system on a chip. In some embodiments, device 900 may be included in a mobile device, which may be battery-powered. Therefore, power consumption by device 900 may be an important design consideration. In the illustrated embodiment, device 900 includes fabric 910, compute complex 920 input/output (I/O) bridge 950, cache/memory controller 945, graphics unit 975, and display unit 965. In some embodiments, device 900 may include other components (not shown) in addition to or in place of the illustrated components, such as video processor encoders and decoders, image processing or recognition elements, computer vision elements, etc.

Fabric 910 may include various interconnects, buses, MUX's, controllers, etc., and may be configured to facilitate communication between various elements of device 900. In some embodiments, portions of fabric 910 may be configured to implement various different communication protocols. In other embodiments, fabric 910 may implement a single communication protocol and elements coupled to fabric 910 may convert from the single communication protocol to other communication protocols internally.

In the illustrated embodiment, compute complex 920 includes bus interface unit (BIU) 925, cache 930, and cores 935 and 940. In various embodiments, compute complex 920 may include various numbers of processors, processor cores and caches. For example, compute complex 920 may include 1, 2, or 4 processor cores, or any other suitable number. In one embodiment, cache 930 is a set associative L2 cache. In some embodiments, cores 935 and 940 may include internal instruction and data caches. In some embodiments, a coherency unit (not shown) in fabric 910, cache 930, or elsewhere in device 900 may be configured to maintain coherency between various caches of device 900. BIU 925 may be configured to manage communication between compute complex 920 and other elements of device 900. Processor cores such as cores 935 and 940 may be configured to execute instructions of a particular instruction set architecture (ISA) which may include operating system instructions and user application instructions. These instructions may be stored in computer readable medium such as a memory coupled to memory controller 945 discussed below.

As used herein, the term “coupled to” may indicate one or more connections between elements, and a coupling may include intervening elements. For example, in FIG. 9, graphics unit 975 may be described as “coupled to” a memory through fabric 910 and cache/memory controller 945. In contrast, in the illustrated embodiment of FIG. 9, graphics unit 975 is “directly coupled” to fabric 910 because there are no intervening elements.

Cache/memory controller 945 may be configured to manage transfer of data between fabric 910 and one or more caches and memories. For example, cache/memory controller 945 may be coupled to an L3 cache, which may in turn be coupled to a system memory. In other embodiments, cache/memory controller 945 may be directly coupled to a memory. In some embodiments, cache/memory controller 945 may include one or more internal caches. Memory coupled to controller 945 may be any type of volatile memory, such as dynamic random access memory (DRAM), synchronous DRAM (SDRAM), double data rate (DDR, DDR2, DDR3, etc.) SDRAM (including mobile versions of the SDRAMs such as mDDR3, etc., and/or low power versions of the SDRAMs such as LPDDR4, etc.), RAMBUS DRAM (RDRAM), static RAM (SRAM), etc. One or more memory devices may be coupled onto a circuit board to form memory modules such as single inline memory modules (SIMMs), dual inline memory modules (DIMMs), etc. Alternatively, the devices may be mounted with an integrated circuit in a chip-on-chip configuration, a package-on-package configuration, or a multi-chip module configuration. Memory coupled to controller 945 may be any type of non-volatile memory such as NAND flash memory, NOR flash memory, nano RAM (NRAM), magneto-resistive RAM (MRAM), phase change RAM (PRAM), Racetrack memory, Memristor memory, etc. As noted above, this memory may store program instructions executable by compute complex 920 to cause the computing device to perform functionality described herein.

Graphics unit 975 may include one or more processors, e.g., one or more graphics processing units (GPUs). Graphics unit 975 may receive graphics-oriented instructions, such as OPENGL®, Metal®, or DIRECT3D® instructions, for example. Graphics unit 975 may execute specialized GPU instructions or perform other operations based on the received graphics-oriented instructions. Graphics unit 975 may generally be configured to process large blocks of data in parallel and may build images in a frame buffer for output to a display, which may be included in the device or may be a separate device. Graphics unit 975 may include transform, lighting, triangle, and rendering engines in one or more graphics processing pipelines. Graphics unit 975 may output pixel information for display images. Graphics unit 975, in various embodiments, may include programmable shader circuitry which may include highly parallel execution cores configured to execute graphics programs, which may include pixel tasks, vertex tasks, and compute tasks (which may or may not be graphics-related).

Display unit 965 may be configured to read data from a frame buffer and provide a stream of pixel values for display. Display unit 965 may be configured as a display pipeline in some embodiments. Additionally, display unit 965 may be configured to blend multiple frames to produce an output frame. Further, display unit 965 may include one or more interfaces (e.g., MIPI® or embedded display port (eDP)) for coupling to a user display (e.g., a touchscreen or an external display).

I/O bridge 950 may include various elements configured to implement: universal serial bus (USB) communications, security, audio, and low-power always-on functionality, for example. I/O bridge 950 may also include interfaces such as pulse-width modulation (PWM), general-purpose input/output (GPIO), serial peripheral interface (SPI), and inter-integrated circuit (I2C), for example. Various types of peripherals and devices may be coupled to device 900 via I/O bridge 950.

In some embodiments, device 900 includes network interface circuitry (not explicitly shown), which may be connected to fabric 910 or I/O bridge 950. The network interface circuitry may be configured to communicate via various networks, which may be wired, wireless, or both. For example, the network interface circuitry may be configured to communicate via a wired local area network, a wireless local area network (e.g., via Wi-Fi™), or a wide area network (e.g., the Internet or a virtual private network). In some embodiments, the network interface circuitry is configured to communicate via one or more cellular networks that use one or more radio access technologies. In some embodiments, the network interface circuitry is configured to communicate using device-to-device communications (e.g., Bluetooth® or Wi-Fi™ Direct), etc. In various embodiments, the network interface circuitry may provide device 900 with connectivity to various types of other devices and networks.

### Example Applications

Turning now to FIG. 10, various types of systems that may include any of the circuits, devices, or system discussed above. System or device 1000, which may incorporate or otherwise utilize one or more of the techniques described herein, may be utilized in a wide range of areas. For example, system or device 1000 may be utilized as part of the hardware of systems such as a desktop computer 1010, laptop computer 1020, tablet computer 1030, cellular or mobile phone 1040, or television 1050 (or set-top box coupled to a television).

Similarly, disclosed elements may be utilized in a wearable device 1060, such as a smartwatch or a health-monitoring device. Smartwatches, in many embodiments, may implement a variety of different functions—for example, access to email, cellular service, calendar, health monitoring, etc. A wearable device may also be designed solely to perform health-monitoring functions, such as monitoring a user's vital signs, performing epidemiological functions such as contact tracing, providing communication to an emergency medical service, etc. Other types of devices are also contemplated, including devices worn on the neck, devices implantable in the human body, glasses or a helmet designed to provide computer-generated reality experiences such as those based on augmented and/or virtual reality, etc.

System or device 1000 may also be used in various other contexts. For example, system or device 1000 may be utilized in the context of a server computer system, such as a dedicated server or on shared hardware that implements a cloud-based service 1070. Still further, system or device 1000 may be implemented in a wide range of specialized everyday devices, including devices 1080 commonly found in the home such as refrigerators, thermostats, security cameras, etc. The interconnection of such devices is often referred to as the “Internet of Things” (IoT). Elements may also be implemented in various modes of transportation. For example, system or device 1000 could be employed in the control systems, guidance systems, entertainment systems, etc. of various types of vehicles 1090.

The applications illustrated in FIG. 10 are merely exemplary and are not intended to limit the potential future applications of disclosed systems or devices. Other example applications include, without limitation: portable gaming devices, music players, data storage devices, unmanned aerial vehicles, etc.

### Example Computer-Readable Medium

The present disclosure has described various example circuits in detail above. It is intended that the present disclosure cover not only embodiments that include such circuitry, but also a computer-readable storage medium that includes design information that specifies such circuitry. Accordingly, the present disclosure is intended to support claims that cover not only an apparatus that includes the disclosed circuitry, but also a storage medium that specifies the circuitry in a format that programs a computing system to generate a simulation model of the hardware circuit, programs a fabrication system configured to produce hardware (e.g., an integrated circuit) that includes the disclosed circuitry, etc. Claims to such a storage medium are intended to cover, for example, an entity that produces a circuit design, but does not itself perform complete operations such as: design simulation, design synthesis, circuit fabrication, etc.

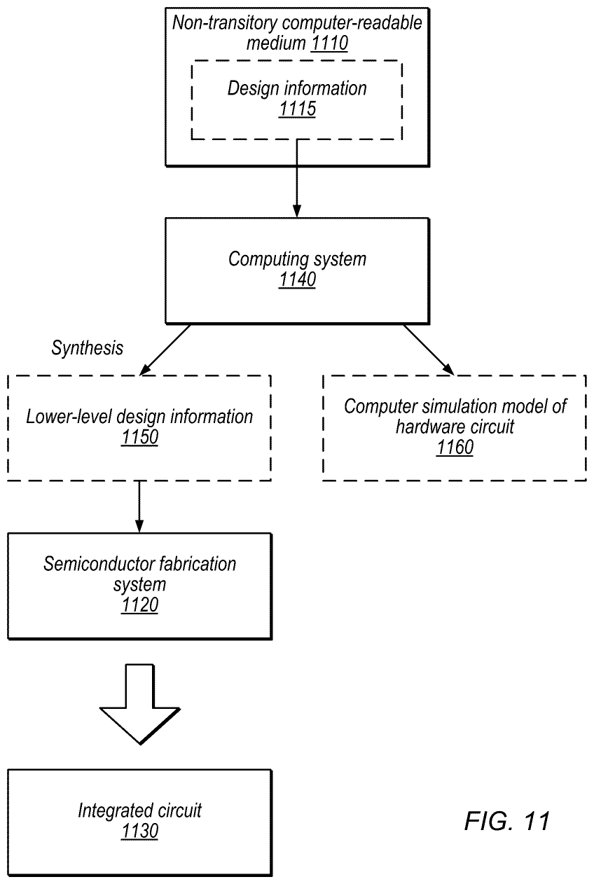

FIG. 11 is a block diagram illustrating an example non-transitory computer-readable storage medium that stores circuit design information, according to some embodiments. In the illustrated embodiment, computing system 1140 is configured to process the design information. This may include executing instructions included in the design information, interpreting instructions included in the design information, compiling, transforming, or otherwise updating the design information, etc. Therefore, the design information controls computing system 1140 (e.g., by programming computing system 1140) to perform various operations discussed below, in some embodiments.

In the illustrated example, computing system 1140 processes the design information to generate both a computer simulation model of a hardware circuit 1160 and lower-level design information 1150. In other embodiments, computing system 1140 may generate only one of these outputs, may generate other outputs based on the design information, or both. Regarding the computing simulation, computing system 1140 may execute instructions of a hardware description language that includes register transfer level (RTL) code, behavioral code, structural code, or some combination thereof. The simulation model may perform the functionality specified by the design information, facilitate verification of the functional correctness of the hardware design, generate power consumption estimates, generate timing estimates, etc.

In the illustrated example, computing system 1140 also processes the design information to generate lower-level design information 1150 (e.g., gate-level design information, a netlist, etc.). This may include synthesis operations, as shown, such as constructing a multi-level network, optimizing the network using technology-independent techniques, technology dependent techniques, or both, and outputting a network of gates (with potential constraints based on available gates in a technology library, sizing, delay, power, etc.). Based on lower-level design information 1150 (potentially among other inputs), semiconductor fabrication system 1120 is configured to fabricate an integrated circuit 1130 (which may correspond to functionality of the simulation model 1160). Note that computing system 1140 may generate different simulation models based on design information at various levels of description, including information 1150, 1115, and so on. The data representing design information 1150 and model 1160 may be stored on medium 1110 or on one or more other media.

In some embodiments, the lower-level design information 1150 controls (e.g., programs) the semiconductor fabrication system 1120 to fabricate the integrated circuit 1130. Thus, when processed by the fabrication system, the design information may program the fabrication system to fabricate a circuit that includes various circuitry disclosed herein.

Non-transitory computer-readable storage medium 1110, may comprise any of various appropriate types of memory devices or storage devices. Non-transitory computer-readable storage medium 1110 may be an installation medium, e.g., a CD-ROM, floppy disks, or tape device; a computer system memory or random access memory such as DRAM, DDR RAM, SRAM, EDO RAM, Rambus RAM, etc.; a non-volatile memory such as a Flash, magnetic media, e.g., a hard drive, or optical storage; registers, or other similar types of memory elements, etc. Non-transitory computer-readable storage medium 1110 may include other types of non-transitory memory as well or combinations thereof. Accordingly, non-transitory computer-readable storage medium 1110 may include two or more memory media; such media may reside in different locations—for example, in different computer systems that are connected over a network.

Design information 1115 may be specified using any of various appropriate computer languages, including hardware description languages such as, without limitation: VHDL, Verilog, SystemC, SystemVerilog, RHDL, M, MyHDL, etc. The format of various design information may be recognized by one or more applications executed by computing system 1140, semiconductor fabrication system 1120, or both. In some embodiments, design information may also include one or more cell libraries that specify the synthesis, layout, or both of integrated circuit 1130. In some embodiments, the design information is specified in whole or in part in the form of a netlist that specifies cell library elements and their connectivity. Design information discussed herein, taken alone, may or may not include sufficient information for fabrication of a corresponding integrated circuit. For example, design information may specify the circuit elements to be fabricated but not their physical layout. In this case, design information may be combined with layout information to actually fabricate the specified circuitry.

Integrated circuit 1130 may, in various embodiments, include one or more custom macrocells, such as memories, analog or mixed-signal circuits, and the like. In such cases, design information may include information related to included macrocells. Such information may include, without limitation, schematics capture database, mask design data, behavioral models, and device or transistor level netlists. Mask design data may be formatted according to graphic data system (GDSII), or any other suitable format.

Semiconductor fabrication system 1120 may include any of various appropriate elements configured to fabricate integrated circuits. This may include, for example, elements for depositing semiconductor materials (e.g., on a wafer, which may include masking), removing materials, altering the shape of deposited materials, modifying materials (e.g., by doping materials or modifying dielectric constants using ultraviolet processing), etc. Semiconductor fabrication system 1120 may also be configured to perform various testing of fabricated circuits for correct operation.

In various embodiments, integrated circuit 1130 and model 1160 are configured to operate according to a circuit design specified by design information 1115, which may include performing any of the functionality described herein. For example, integrated circuit 1130 may include any of various elements shown in FIGS. 2, 3, 4 and 5. Further, integrated circuit 1130 may be configured to perform various functions described herein in conjunction with other components. Further, the functionality described herein may be performed by multiple connected integrated circuits.

As used herein, a phrase of the form “design information that specifies a design of a circuit configured to . . . ” does not imply that the circuit in question must be fabricated in order for the element to be met. Rather, this phrase indicates that the design information describes a circuit that, upon being fabricated, will be configured to perform the indicated actions or will include the specified components. Similarly, stating “instructions of a hardware description programming language” that are “executable” to program a computing system to generate a computer simulation model” does not imply that the instructions must be executed in order for the element to be met, but rather specifies characteristics of the instructions. Additional features relating to the model (or the circuit represented by the model) may similarly relate to characteristics of the instructions, in this context. Therefore, an entity that sells a computer-readable medium with instructions that satisfy recited characteristics may provide an infringing product, even if another entity actually executes the instructions on the medium.

Note that a given design, at least in the digital logic context, may be implemented using a multitude of different gate arrangements, circuit technologies, etc. As one example, different designs may select or connect gates based on design tradeoffs (e.g., to focus on power consumption, performance, circuit area, etc.). Further, different manufacturers may have proprietary libraries, gate designs, physical gate implementations, etc. Different entities may also use different tools to process design information at various layers (e.g., from behavioral specifications to physical layout of gates).

Once a digital logic design is specified, however, those skilled in the art need not perform substantial experimentation or research to determine those implementations. Rather, those of skill in the art understand procedures to reliably and predictably produce one or more circuit implementations that provide the function described by the design information. The different circuit implementations may affect the performance, area, power consumption, etc. of a given design (potentially with tradeoffs between different design goals), but the logical function does not vary among the different circuit implementations of the same circuit design.

In some embodiments, the instructions included in the design information instructions provide RTL information (or other higher-level design information) and are executable by the computing system to synthesize a gate-level netlist that represents the hardware circuit based on the RTL information as an input. Similarly, the instructions may provide behavioral information and be executable by the computing system to synthesize a netlist or other lower-level design information. The lower-level design information may program fabrication system 1120 to fabricate integrated circuit 1130.

The various techniques described herein may be performed by one or more computer programs. The term “program” is to be construed broadly to cover a sequence of instructions in a programming language that a computing device can execute. These programs may be written in any suitable computer language, including lower-level languages such as assembly and higher-level languages such as Python. The program may be written in a compiled language such as C or C++, or an interpreted language such as JavaScript.

Program instructions may be stored on a “computer-readable storage medium” or a “computer-readable medium” in order to facilitate execution of the program instructions by a computer system. Generally speaking, these phrases include any tangible or non-transitory storage or memory medium. The terms “tangible” and “non-transitory” are intended to exclude propagating electromagnetic signals, but not to otherwise limit the type of storage medium. Accordingly, the phrases “computer-readable storage medium” or a “computer-readable medium” are intended to cover types of storage devices that do not necessarily store information permanently (e.g., random access memory (RAM)). The term “non-transitory,” accordingly, is a limitation on the nature of the medium itself (i.e., the medium cannot be a signal) as opposed to a limitation on data storage persistency of the medium (e.g., RAM vs. ROM).

The phrases “computer-readable storage medium” and “computer-readable medium” are intended to refer to both a storage medium within a computer system as well as a removable medium such as a CD-ROM, memory stick, or portable hard drive. The phrases cover any type of volatile memory within a computer system including DRAM, DDR RAM, SRAM, EDO RAM, Rambus RAM, etc., as well as non-volatile memory such as magnetic media, e.g., a hard drive, or optical storage. The phrases are explicitly intended to cover the memory of a server that facilitates downloading of program instructions, the memories within any intermediate computer system involved in the download, as well as the memories of all destination computing devices. Still further, the phrases are intended to cover combinations of different types of memories.

In addition, a computer-readable medium or storage medium may be located in a first set of one or more computer systems in which the programs are executed, as well as in a second set of one or more computer systems which connect to the first set over a network. In the latter instance, the second set of computer systems may provide program instructions to the first set of computer systems for execution. In short, the phrases “computer-readable storage medium” and “computer-readable medium” may include two or more media that may reside in different locations, e.g., in different computers that are connected over a network.

The present disclosure includes references to “an “embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more of the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be realized, but rather to recognize the technical reality that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to a singular form of an item (i.e., a noun or noun phrase preceded by “a,” “an,” or “the”) are, unless context clearly dictates otherwise, intended to mean “one or more.” Reference to “an item” in a claim thus does not, without accompanying context, preclude additional instances of the item. A “plurality” of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or” is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of elements. This phrase is not to be interpreted to require that there is at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third” when applied to a feature do not imply any type of ordering (e.g., spatial, temporal, logical, etc.), unless stated otherwise.

The phrase “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some task even if the structure is not currently being operated. Thus, an entity described or recited as being “configured to” perform some task refers to something physical, such as a device, circuit, a system having a processor unit and a memory storing program instructions executable to implement the task, etc. This phrase is not used herein to refer to something intangible.

In some cases, various units/circuits/components may be described herein as performing a set of tasks or operations. It is understood that those entities are “configured to” perform those tasks/operations, even if not specifically noted.

The term “configured to” is not intended to mean “configurable to.” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function.

For purposes of United States patent applications based on this disclosure, reciting in a claim that a structure is “configured to” perform one or more tasks is expressly intended not to invoke 35 U.S.C. § 112(f) for that claim element. Should Applicant wish to invoke Section 112(f) during prosecution of a United States patent application based on this disclosure, it will recite claim elements using the “means for” [performing a function] construct.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), functional unit, memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “decode unit” may be described as performing the function of “processing an opcode of an instruction and routing that instruction to one or more of a plurality of functional units,” which means that the decode unit is “configured to” perform this function. This specification of function is sufficient, to those skilled in the computer arts, to connote a set of possible structures for the circuit.

In various embodiments, as discussed in the preceding paragraph, circuits, units, and other elements may be defined by the functions or operations that they are configured to implement. The arrangement of such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used to transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits or portions thereof may also be custom-designed in a schematic editor and captured into the integrated circuit design along with synthesized circuitry. The integrated circuits may include transistors and other circuit elements (e.g., passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

1. An apparatus, comprising:
processor circuitry configured to operate based on an input clock signal at different input clock frequencies in different performance states;
phased-locked loop (PLL) circuitry configured to provide the input clock signal at the different input clock frequencies;
bypass circuitry configured to provide a bypass clock signal during different re-lock intervals in which the PLL circuitry adjusts frequency of the input clock signal for a change from a first performance state to a second performance state, including to:
provide the bypass clock signal at a first frequency during a first re-lock interval; and
provide the bypass clock signal at a second frequency during a second re-lock interval, wherein the second frequency is different than the first frequency.

2. The apparatus of claim 1, wherein the bypass circuitry is configured to determine the first frequency of the first re-lock interval based on a first origin performance state corresponding to the first re-lock interval.

3. The apparatus of claim 1, wherein the bypass circuitry is configured to determine the first frequency of the first re-lock interval based on a first target performance state corresponding to the first re-lock interval.

4. The apparatus of claim 1, wherein the bypass circuitry is configured to determine the first frequency of the first re-lock interval based on a difference between a first target performance state and a first origin performance state corresponding to the first re-lock interval.

5. The apparatus of claim 1, further comprising:
selection circuitry configured to select between the input clock signal generated by the PLL circuitry and a second input signal associated with the bypass clock signal; and
dither circuitry configured to dither the bypass clock signal during a given re-lock interval.

6. The apparatus of claim 5, wherein the dither circuitry is further configured to dither the bypass clock signal when the second performance state is greater than the first performance state, but not when the second performance state is lower than the first performance state.

7. The apparatus of claim 5, wherein the dither circuitry is further configured to dither the bypass clock signal by an amount based on a difference between the second performance state and the first performance state.

8. The apparatus of claim 5, wherein the dither circuitry is further configured to dither an output of the selection circuitry.

9. The apparatus of claim 5, wherein the dither circuitry is configured to dither the bypass clock signal and provide a dithered bypass block signal as the second input signal to the selection circuitry.

10. The apparatus of claim 1, wherein the bypass circuitry includes:
PLL circuitry configured to generate the bypass clock signal at the first frequency and at the second frequency during the first and second re-lock intervals.

11. A method comprising:
operating, by a computing system, based on an input clock signal at different input clock frequencies in different performance states;
providing, by a phase-locked loop (PLL) clock generator, the input clock signal at the different input clock frequencies;
providing, by the computing system, a bypass clock signal during different re-lock intervals in which the PLL clock generator adjusts frequency of the input clock signal for a change from a first performance state to a second performance state, including to:
providing the bypass clock signal at a first frequency during a first re-lock interval; and
providing the bypass clock signal at a second frequency during a second re-lock interval, wherein the second frequency is different than the first frequency.

12. The method of claim 11, wherein the computing system is configured to determine the first frequency of the first re-lock interval based on a first origin performance state corresponding to the first re-lock interval.

13. The method of claim 11, wherein the computing system is configured to determine the first frequency of the first re-lock interval based on a first target performance state corresponding to the first re-lock interval.

14. The method of claim 11, wherein the computing system is configured to determine the first frequency of the first re-lock interval based on a difference between a first target performance state and a first origin performance state corresponding to the first re-lock interval.

15. The method of claim 11, wherein the computing system is further configured to select between the input clock signal generated by the PLL clock generator and a second input signal associated with the bypass clock signal and dither the bypass clock signal during a given re-lock interval.

16. The method of claim 15, wherein the computing system is further configured to dither the bypass clock signal when the second performance state is greater than the first performance state, but not when the second performance state is lower than the first performance state.

17. The method of claim 15, wherein the computing system is further configured to dither the bypass clock signal by an amount based on a difference between the second performance state and the first performance state.

18. A non-transitory computer-readable medium having instructions of a hardware description programming language stored thereon that, when processed by a computing system, program the computing system to generate a computer simulation model, wherein the model represents a hardware circuit that includes:
processor circuitry configured to operate based on an input clock signal at different input clock frequencies in different performance states;
phased-locked loop (PLL) circuitry configured to provide the input clock signal at the different input clock frequencies;
bypass circuitry configured to provide a bypass clock signal during different re-lock intervals in which the PLL circuitry adjusts frequency of the input clock signal for a change from a first performance state to a second performance state, including to:
provide the bypass clock signal at a first frequency during a first re-lock interval; and
provide the bypass clock signal at a second frequency during a second re-lock interval, wherein the second frequency is different than the first frequency.

19. The non-transitory computer-readable medium of claim 18, wherein the bypass circuitry is configured to determine the first frequency of the first re-lock interval based on a first origin performance state corresponding to the first re-lock interval.

20. The non-transitory computer-readable medium of claim 18, wherein the bypass circuitry is configured to determine the first frequency of the first re-lock interval based on a first target performance state corresponding to the first re-lock interval.
